(19) United States
(12) Patent Application Publication
(10) Pub. No.: US 2024/0258489 A1
(43) Pub. Date: Aug. 1, 2024

(54) DISPLAY DEVICE

(71) Applicant: Samsung Electronics Co., Ltd., Suwon-si (KR)

(72) Inventors: Woon Bae KIM, Suwon-si (KR); Ye Chung CHUNG, Suwon-si (KR)

(73) Assignee: Samsung Electronics Co., Ltd., Suwon-si (KR)

(21) Appl. No.: 18/491,145

(22) Filed: Oct. 20, 2023

(30) Foreign Application Priority Data
Jan. 27, 2023 (KR) 10-2023-0010851

(51) Int. Cl. H01L 33/62; H01L 25/075; H01L 33/64

(52) U.S. Cl. CPC H01L 33/62; H01L 25/0753; H01L 33/64

(57) ABSTRACT

A display device is provided. The display device includes a substrate including a display region and a non-display region adjacent to the display region in a first horizontal direction, a light-emitting element layer on an upper surface of the substrate in the display region, a thin-film substrate connected to the upper surface of the substrate in the non-display region, a first semiconductor chip on a lower surface of the substrate, at least a portion of the first semiconductor chip overlapping with the thin-film substrate in a vertical direction, and a first through-via in the non-display region, the first through-via extending through the substrate in the vertical direction, the first through-via electrically connecting the thin-film substrate and the first semiconductor chip to each other.

### CROSS-REFERENCE TO RELATED APPLICATION

This application claims priority from Korean Patent Application No. 10-2023-0010851 filed on Jan. 27, 2023 in the Korean Intellectual Property Office, and all the benefits accruing therefrom under 35 U.S.C. 119, the contents of which in their entirety are herein incorporated by reference.

### BACKGROUND

### Technical Field

The present disclosure relates to display devices.

### Description of Related Art

As the information society develops, demand for a display device for displaying an image is increasing in various forms. The display device may be a flat display device such as a liquid crystal display device, a field emission display device, and a light-emitting display device. The light-emitting display device may include an organic light-emitting display device including an organic light-emitting diode element as a light-emitting element, an inorganic light-emitting display device including an inorganic semiconductor element as a light-emitting element, or a micro-LED display device including an ultra-small light-emitting diode element or a micro light-emitting diode element as a light-emitting element.

Recently, a head mounted display (HMD) including the light-emitting display device has been developed. The HMD is a glasses-type monitor device for virtual reality (VR) or augmented reality (AR) which a user wears in a form of glasses or a helmet whose focus is formed at a point close to eyes of the user.

### SUMMARY

Some example embodiments of the present disclosure provide display devices in which a semiconductor chip is disposed on a lower surface of a substrate to reduce a region size of a non-display region (e.g., to reduce an area constraint due to the non-display region), thereby reducing a size of a display device.

According to an example embodiment of the present disclosure, a display device may include a substrate including a display region and a non-display region adjacent to the display region in a first horizontal direction, a light-emitting element layer on an upper surface of the substrate in the display region, a thin-film substrate connected to the upper surface of the substrate in the non-display region, a first semiconductor chip on a lower surface of the substrate, at least a portion of the first semiconductor chip overlapping with the thin-film substrate in a vertical direction, and a first through-via in the non-display region, the first through-via extending through the substrate in the vertical direction, the first through-via electrically connecting the thin-film substrate and the first semiconductor chip to each other.

According to an example embodiment of the present disclosure, a display device may include a substrate including silicon (Si), a light-emitting element layer on an upper surface of the substrate, a thin-film substrate connected to the upper surface of the substrate, the thin-film substrate spaced apart from the light-emitting element layer in a horizontal direction, a first semiconductor chip on a lower surface of the substrate, at least a portion of the first semiconductor chip overlapping with the thin-film substrate in a vertical direction, a molding layer on the lower surface of the substrate, the molding layer surrounding a sidewall of the first semiconductor chip, and a first through-via extending through the substrate in the vertical direction, the first through-via electrically connecting the thin-film substrate and the first semiconductor chip to each other.

According to an example embodiment of the present disclosure, a display device may include a substrate including a display region and a non-display region adjacent to the display region in a horizontal direction, the substrate including silicon (Si), a light-emitting element layer disposed on an upper surface of the substrate in the display region, an upper substrate on the light-emitting element layer in the display region, a thin-film substrate in the non-display region, one end of the thin-film substrate connected to the upper surface of the substrate, a circuit board connected to an opposite end of the thin-film substrate, a semiconductor chip on a lower surface of the substrate, at least a portion of the semiconductor chip overlapping with the thin-film substrate in a vertical direction, a molding layer on the lower surface of the substrate, the molding layer surrounding a sidewall of the semiconductor chip, a lower surface of the molding layer being coplanar with a lower surface of the semiconductor chip, a sidewall of the molding layer aligned with a sidewall of the substrate in the vertical direction, a first through-via in the non-display region, the first through-via extending through the substrate in the vertical direction, the first through-via electrically connecting the thin-film substrate and the semiconductor chip to each other, a second through-via in the non-display region, to the second through-via extending through the substrate in the vertical direction, the second through-via spaced apart from the first through-via in the horizontal direction, the second through-via electrically connected to the semiconductor chip, and a conductive pad on the upper surface of the substrate, the conductive pad electrically connecting the second through-via and the light-emitting element layer to each other.

Example embodiments of the present disclosure is not limited to the example embodiments as mentioned above, and other example embodiments as not mentioned will be clearly understood by those skilled in the art from descriptions set forth below.

### BRIEF DESCRIPTION OF DRAWINGS

The above and other aspects and features of the present disclosure will become more apparent by describing in detail illustrative example embodiments thereof with reference to the attached drawings, in which:

FIG. 1 is a plan view for illustrating a display device according to an example embodiment of the present disclosure;

FIG. 2 is a cross-sectional view taken along a line A-A′ in FIG. 1;

FIG. 3 to FIG. 8 are diagrams of intermediate structures corresponding to intermediate steps for illustrating a method for manufacturing a display device according to an example embodiment of the present disclosure;

FIG. 9 is a cross-sectional view for illustrating a display device according to an example embodiment of the present disclosure;

FIG. 10 is a cross-sectional view for illustrating a display device according to an example embodiment of the present disclosure;

FIG. 11 is a cross-sectional view for illustrating a display device according to an example embodiment of the present disclosure;

FIG. 12 is a cross-sectional view for illustrating a display device according to an example embodiment of the present disclosure;

FIG. 13 is a cross-sectional view for illustrating a display device according to an example embodiment of the present disclosure;

FIG. 14 is a cross-sectional view for illustrating a display device according to an example embodiment of the present disclosure; and

FIG. 15 is a plan view for illustrating a display device according to an example embodiment of the present disclosure.

### DETAILED DESCRIPTIONS

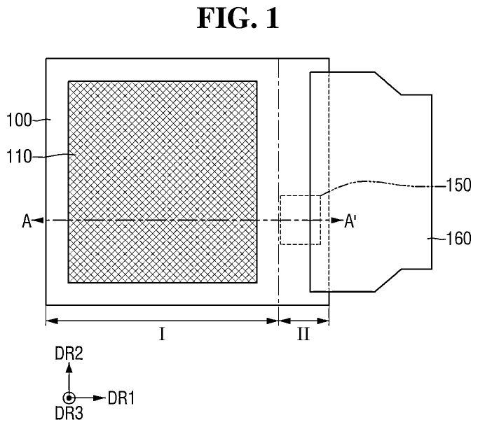

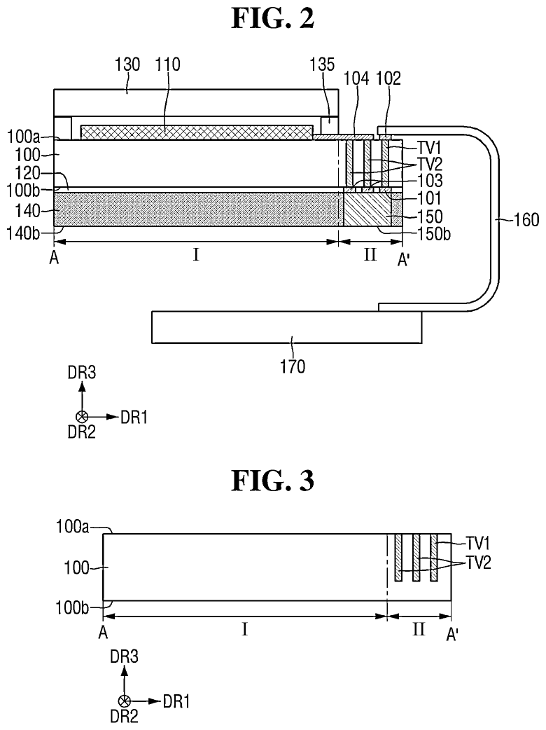

Hereinafter, a display device according to some example embodiments of the present disclosure is described with reference to FIGS. 1 and 2.

FIG. 1 is a plan view for illustrating a display device according to an example embodiment of the present disclosure. FIG. 2 is a cross-sectional view taken along a line A-A′ in FIG. 1.

Referring to FIG. 1 and FIG. 2, the display device according to an example embodiment of the present disclosure includes a substrate 100, a first through-via TV1, a second through-via TV2, first to fourth conductive pads 101 to 104, a light-emitting element layer 110, an insulating layer 120, an upper substrate 130, a partitioning wall 135, a molding layer 140, a first semiconductor chip 150, a thin-film substrate 160 and a circuit board 170.

Hereinafter, each of a first horizontal direction DR1 and a second horizontal direction DR2 may be defined as a direction parallel to an upper surface 100a of the substrate 100. The second horizontal direction DR2 may be defined as a direction perpendicular to the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the upper surface 100a of the substrate 100.

The substrate 100 may include a display region I and a non-display region II. The display region I may be a region where an image is displayed, while the non-display region II may be a region in which an image is not displayed. For example, the non-display region II may be directly adjacent to the display region I in the first horizontal direction DR1. However, the present disclosure is not limited thereto. In some example embodiments, the non-display region II may surround the display region I in a plane defined by the first and second horizontal directions DR1 and DR2. The substrate 100 may include, for example, silicon (Si). That is, the substrate 100 may be a silicon substrate.

The light-emitting element layer 110 may be disposed on the upper surface 100a of the substrate 100 and in the display region I. The light-emitting element layer 110 may include a plurality of light-emitting elements. For example, each of the plurality of light-emitting elements may be a micro light-emitting diode or an organic light-emitting diode. The partitioning wall 135 may be disposed on the upper surface 100a of the substrate 100 and in the display region I. The partitioning wall 135 may surround a sidewall of the light-emitting element layer 110. For example, the partitioning wall 135 may include silicon (Si). For example, the partitioning wall 135 may include a silicon single crystal layer. However, the present disclosure is not limited thereto.

The upper substrate 130 may be disposed on the upper surface 100a of the substrate 100 and in the display region I. For example, the display region I may be defined as a region where the light-emitting element layer 110, the partitioning wall 135 and the upper substrate 130 are disposed. For example, the upper substrate 130 may be disposed on both of the upper surface of the light-emitting element layer 110 and the upper surface of the partitioning wall 135 and in the display region I. For example, the light-emitting element layer 110 may be covered with the upper substrate 130 and the partitioning wall 135. For example, the upper substrate 130 may include a transparent substrate such as sapphire substrate (Al2O3), glass, etc. However, the present disclosure is not limited thereto. In some example embodiments, the upper substrate 130 may include a conductive substrate made of GaN, SiC, ZnO, Si, GaP, or GaAs.

Each of the first through-via TV1 and the second through-via TV2 may be disposed in the non-display region II. Each of the first through-via TV1 and the second through-via TV2 may extend through the substrate 100 in the vertical direction DR3. For example, each of the first through-via TV1 and the second through-via TV2 may extend from a lower surface 100b of the substrate 100 to the upper surface 100a of the substrate 100 in the vertical direction DR3. For example, the first through-via TV1 may be spaced apart from the second through-via TV2 in the first horizontal direction DR1. For example, the second through-via TV2 may be closer to the display region I than the first through-via TV1 may be.

In the cross-sectional view of FIG. 2, it is shown that one first through-via TV1 and two second through-vias TV2 are disposed. However, this is intended only for convenience of description, and the present disclosure is not limited thereto. That is, the number of the first through-vias TV1 arranged in the non-display region II and the number of the second through-vias TV2 arranged in the non-display region II are not limited thereto. Each of the first through-via TV1 and the second through-via TV2 may include a conductive material.

The first conductive pad 101 may be disposed on the lower surface 100b of the substrate 100 and in the non-display region II. The first conductive pad 101 may be connected to a bottom surface of the first through-via TV1. The second conductive pad 102 may be disposed on the upper surface 100a of the substrate 100 and in the non-display region II. The second conductive pad 102 may be connected to a top surface of the first through-via TV1. The third conductive pad 103 may be disposed on the lower surface 100b of the substrate 100 and in the non-display region II. The third conductive pad 103 may be connected to a bottom surface of the second through-via TV2.

The fourth conductive pad 104 may be disposed on the upper surface 100a of the substrate 100 and in both of the display region I and the non-display region II. The fourth conductive pad 104 may be connected to the light-emitting element layer 110. For example, the fourth conductive pad 104 may extend in the first horizontal direction DR1 so as to be connected to a top surface of the second through-via TV2. For example, at least a portion of the partitioning wall 135 may be disposed on the fourth conductive pad 104. For example, at least a portion of the partitioning wall 135 may contact the fourth conductive pad 104. However, the present disclosure is not limited thereto. Each of the first to fourth conductive pads 101, 102, 103, and 104 may include a conductive material.

The insulating layer 120 may be disposed on the lower surface 100b of the substrate 100 and in both of the display region I and the non-display region II. For example, the insulating layer 120 may surround a sidewall of each of the first conductive pad 101 and the third conductive pad 103. That is, each of the first conductive pad 101 and the third conductive pad 103 may be disposed in the insulating layer 120. The insulating layer 120 may include an insulating material. For example, the insulating layer 120 may include silicon oxide (SiO2).

The thin-film substrate 160 may be connected on the upper surface 100a of the substrate 100 and in the non-display region II. For example, one end of the thin-film substrate 160 may be connected to the second conductive pad 102. The thin-film substrate 160 may be, for example, a flexible film such as a chip on film (COF). The circuit board 170 may be connected to the other end of the thin-film substrate 160. For example, the circuit board 170 may be a flexible printed circuit board (FPCB), a printed circuit board (PCB) or a flexible printed circuit (FPC).

The first semiconductor chip 150 may be disposed on the lower surface 100b of the substrate 100 and in the non-display region II. At least a portion of the first semiconductor chip 150 may overlap the thin-film substrate 160 in the vertical direction DR3. For example, at least a portion of the first semiconductor chip 150 may overlap a portion of the thin-film substrate 160 connected to the second conductive pad 102 in the vertical direction DR3.

The first semiconductor chip 150 may contact each of the first conductive pad 101, the third conductive pad 103, and the insulating layer 120. The first semiconductor chip 150 may be electrically connected to the thin-film substrate 160 via the first conductive pad 101, the first through-via TV1, and the second conductive pad 102. Further, the first semiconductor chip 150 may be electrically connected to the light-emitting element layer 110 via the third conductive pad 103, the second through-via TV2 and the fourth conductive pad 104. For example, the first semiconductor chip 150 may include a display driver integrated circuit (DDI) or a timing controller (TCON).

The molding layer 140 may be disposed on the lower surface 100b of the substrate 100 and in each of the display region I and the non-display region II. The molding layer 140 may surround a sidewall of the first semiconductor chip 150 while being disposed on a lower surface of the insulating layer 120. That is, the first semiconductor chip 150 may be disposed in the molding layer 140. For example, a sidewall of the molding layer 140 may be aligned with a sidewall of the substrate 100 in the vertical direction DR3.

For example, a lower surface 140b of the molding layer 140 may be coplanar with a lower surface 150b of the first semiconductor chip 150. For example, the molding layer 140 may include an epoxy molding compound (EMC), or a hybrid material of two or more types of silicon. However, the present disclosure is not limited thereto.

In the display device according to some example embodiments of the present disclosure, the light-emitting element layer 110 may be disposed on the upper surface 100a of the substrate 100, the thin-film substrate 160 may be connected to the upper surface 100a of the substrate 100, and the first semiconductor chip 150 may be disposed on the lower surface 100b of the substrate 100. That is, as the first semiconductor chip 150 is disposed on the lower surface 100b of the substrate 100, a region size of the non-display region II to which the thin-film substrate 160 is connected may be reduced. Thus, the display device according to some example embodiments of the present disclosure may have a reduced size.

Hereinafter, a method for manufacturing a display device according to an example embodiment of the present disclosure will be described with reference to FIG. 2 to FIG. 8.

FIG. 3 to FIG. 8 are diagrams of intermediate structures corresponding to intermediate steps for illustrating a method for manufacturing a display device according to an example embodiment of the present disclosure.

Referring to FIG. 3, the substrate 100 including the display region I and the non-display region II disposed directly adjacent to display region I in the first horizontal direction DR1 may be provided.

Subsequently, each of the first through-via TV1 and the second through-via TV2 may be formed in the substrate 100. The second through-via TV2 may be spaced apart from the first through-via TV1 in the first horizontal direction DR1. For example, each of the first through-via TV1 and the second through-via TV2 may extend from the upper surface 100a of the substrate 100 toward the lower surface 100b of the substrate 100. In this case, a lower surface of each of the first through-via TV1 and the second through-via TV2 may contact the substrate 100. In other words, a lower surface of each of the first through-via TV1 and the second through-via TV2 may extend to a certain depth from the top surface 100a of the substrate 100 and may not reach the bottom surface 100b of the substrate 100.

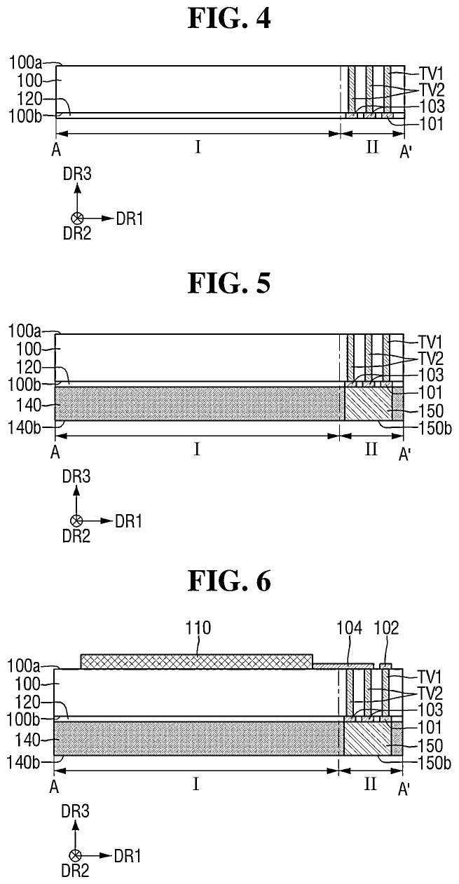

Referring to FIG. 4, a portion of the lower surface 100b of the substrate 100 may be etched to expose each of the first through-via TV1 and the second through-via TV2. Subsequently, the first conductive pad 101, the third conductive pad 103, and insulating layer 120 may be formed on the lower surface 100b of the substrate 100. For example, each of the first conductive pad 101 and the third conductive pad 103 may be formed on the lower surface 100b of the substrate 100 and in the non-display region II. Further, the insulating layer 120 may be formed on the lower surface 100b of the substrate 100 and in each of the display region I and the non-display region II.

For example, the first conductive pad 101 may be connected to the first through-via TV1. The third conductive pad 103 may be connected to the second through-via TV2. The insulating layer 120 may surround a sidewall of each of the first conductive pad 101 and the third conductive pad 103 while being disposed on the lower surface 100b of the substrate 100.

Referring to FIG. 5, the first semiconductor chip 150 may be formed on a lower surface of both of the first conductive pad 101 and the third conductive pad 103 and in the non-display region II. The first semiconductor chip 150 may be connected to each of the first conductive pad 101 and the third conductive pad 103.

Subsequently, the molding layer 140 may be formed on the lower surface of the insulating layer 120 and in each of the display region I and the non-display region II. For example, the molding layer 140 may surround a sidewall and a lower surface of the first semiconductor chip 150. Subsequently, a planarization process (for example, a chemical mechanical polishing (CMP) process) may be performed such that a lower surface of the first semiconductor chip 150 may be exposed. For example, after performing the planarization process (e.g., the CMP process), the lower surface 140b of the molding layer 140 and the lower surface 150b of the first semiconductor chip 150 may be coplanar with each other.

Referring to FIG. 6, the light-emitting element layer 110 may be formed on the upper surface 100a of the substrate 100 and in the display region I. Further, the second conductive pad 102 may be formed on the upper surface 100a of the substrate 100 and in the non-display region II. The second conductive pad 102 may be connected to the first through-via TV1. Further, the fourth conductive pad 104 may be formed on the upper surface 100a of the substrate 100 and in each of the display region I and the non-display region II. The fourth conductive pad 104 may be connected to each of the light-emitting element layer 110 and the second through-via TV2.

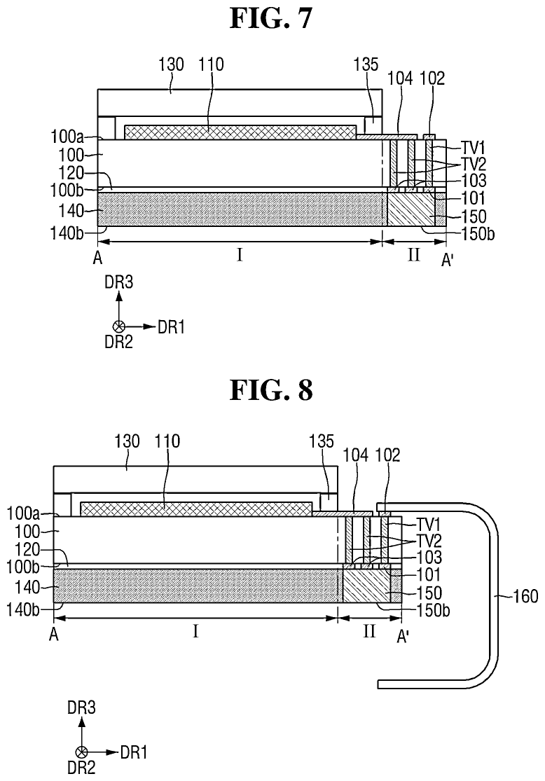

Referring to FIG. 7, the partitioning wall 135 and the upper substrate 130 may be formed on the upper surface 100a of the substrate 100 and in the display region I. For example, the partitioning wall 135 may surround a sidewall of the light-emitting element layer 110 while being disposed on the upper surface 100a of the substrate 100. The upper substrate 130 may be formed on an upper surface of each of the light-emitting element layer 110 and the partitioning wall 135. That is, the light-emitting element layer 110 may be covered with the upper substrate 130 and the partitioning wall 135.

Referring to FIG. 8, the thin-film substrate 160 may be connected to the second conductive pad 102. Referring to FIG. 2, the thin-film substrate 160 may be connected to the circuit board 170. In this manufacturing process, the display device as shown in FIG. 2 may be manufactured.

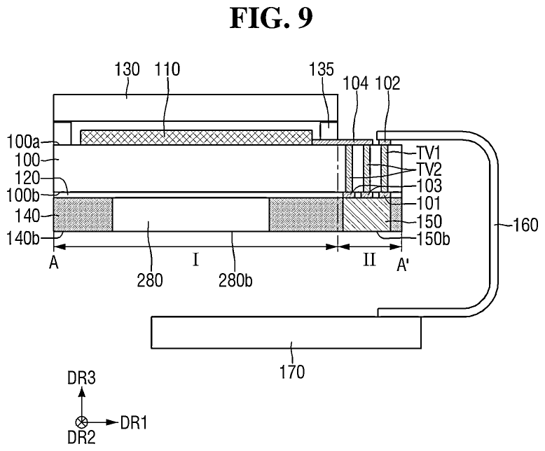

Hereinafter, a display device according to another example embodiments of the present disclosure will be described with reference to FIG. 9. Differences thereof from the display device as shown in FIG. 1 and FIG. 2 will be mainly described.

FIG. 9 is a cross-sectional view for illustrating a display device according to an example embodiment of the present disclosure.

Referring to FIG. 9, in the display device according to an example embodiment of the present disclosure, a heat transfer unit 280 may be disposed on the lower surface 100b of the substrate 100.

For example, the heat transfer unit 280 may be disposed on the lower surface 100b of the substrate 100 and in the display region I. For example, the heat transfer unit 280 may overlap the light-emitting element layer 110 in the vertical direction DR3. The heat transfer unit 280 may be disposed in the molding layer 140. That is, the molding layer 140 may surround a sidewall of the heat transfer unit 280. For example, the first semiconductor chip 150 may be spaced apart from the heat transfer unit 280 in the first horizontal direction DR1.

For example, each of the lower surface 150b of the first semiconductor chip 150, the lower surface 140b of the molding layer 140, and a lower surface 280b of the heat transfer unit 280 may be coplanar with each other. However, the present disclosure is not limited thereto. In some example embodiments, the heat transfer unit 280 may be buried in the molding layer 140. That is, the molding layer 140 may cover the lower surface 280b of the heat transfer unit 280. For example, the heat transfer unit 280 may contact a lower surface of the insulating layer 120.

The heat transfer unit 280 may perform a function of dissipating internal heat in the substrate 100 to an outside out of the display device. For example, the heat transfer unit 280 may include a material with high thermal conductivity. For example, the heat transfer unit 280 may include silicon (Si) or a metal.

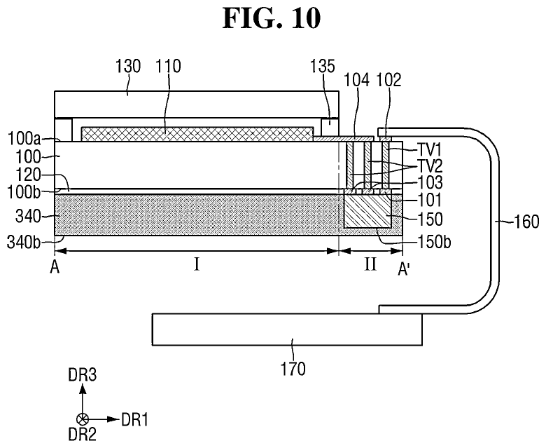

Hereinafter, with reference to FIG. 10, a display device according to still another example embodiment of the present disclosure will be described. Differences thereof from the display device as shown in FIG. 1 and FIG. 2 will be mainly described.

FIG. 10 is a cross-sectional view for illustrating a display device according to an example embodiment of the present disclosure.

Referring to FIG. 10, in the display device according to an example embodiment of the present disclosure, a molding layer 340 may cover the lower surface 150b of the first semiconductor chip 150.

For example, the first semiconductor chip 150 may be embedded in the molding layer 340. That is, the molding layer 340 may cover the lower surface 150b of the first semiconductor chip 150. A lower surface 340b of the molding layer 340 may be positioned at a lower vertical level than that of the lower surface 150b of the first semiconductor chip 150.

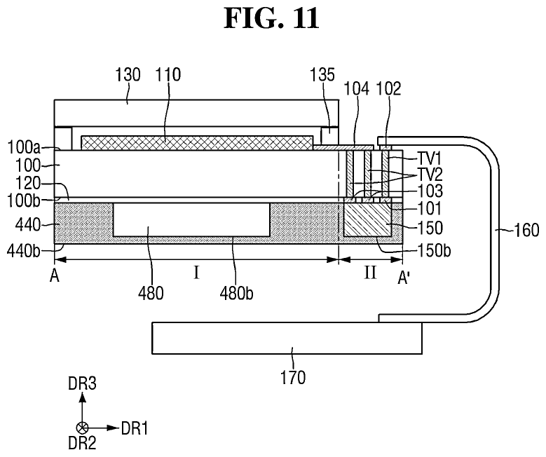

Hereinafter, with reference to FIG. 11, a display device according to still another example embodiment of the present disclosure will be described. Differences thereof from the display device as shown in FIG. 1 and FIG. 2 will be mainly described.

FIG. 11 is a cross-sectional view for illustrating a display device according to an example embodiment of the present disclosure.

Referring to FIG. 11, in the display device according to an example embodiment of the present disclosure, a heat transfer unit 480 may be disposed on the lower surface 100b of the substrate 100. Further, a molding layer 440 may cover the lower surface 150b of the first semiconductor chip 150 and a lower surface 480b of the heat transfer unit 480.

For example, the heat transfer unit 480 may be disposed on the lower surface 100b of the substrate 100 and in the display region I. For example, the heat transfer unit 480 may overlap the light-emitting element layer 110 in the vertical direction DR3. The heat transfer unit 480 may be disposed in the molding layer 440. That is, the molding layer 440 may surround a sidewall of the heat transfer unit 480. For example, the first semiconductor chip 150 may be spaced apart from the heat transfer unit 480 in the first horizontal direction DR1. For example, the heat transfer unit 480 may contact the lower surface of the insulating layer 120.

For example, each of the first semiconductor chip 150 and the heat transfer unit 480 may be buried in the molding layer 440. That is, the molding layer 440 may cover each of the lower surface 150b of the first semiconductor chip 150 and the lower surface 480b of the heat transfer unit 480. A lower surface 440b of the molding layer 440 may be positioned at a lower vertical level than that of each of the lower surface 150b of the first semiconductor chip 150 and the lower surface 480b of the heat transfer unit 480.

The heat transfer unit 480 may perform a function of dissipating internal heat of the substrate 100 to an outside out of the display device. For example, the heat transfer unit 480 may include a material with high thermal conductivity. For example, the heat transfer unit 480 may include silicon (Si) or a metal.

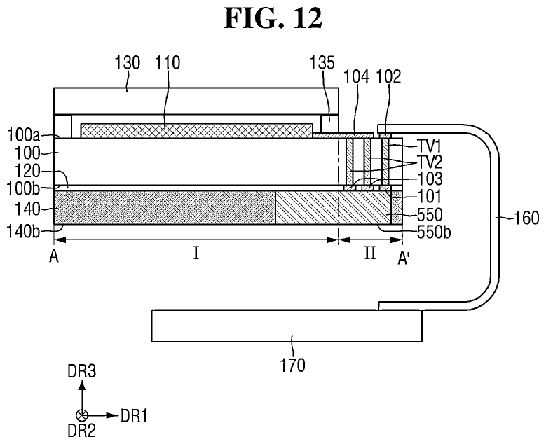

Hereinafter, a display device according to still another example embodiment of the present disclosure will be described with reference to FIG. 12. Differences thereof from the display device as shown in FIG. 1 and FIG. 2 will be mainly described.

FIG. 12 is a cross-sectional view for illustrating a display device according to an example embodiment of the present disclosure.

Referring to FIG. 12, in the display device according to an example embodiment of the present disclosure, at least a portion of a first semiconductor chip 550 may overlap the light-emitting element layer 110 in the vertical direction DR3.

For example, the first semiconductor chip 550 may be disposed on the lower surface 100b of the substrate 100 and in the display region I and the non-display region II. The first semiconductor chip 550 may be disposed in the molding layer 140. That is, the molding layer 140 may surround a sidewall of the first semiconductor chip 550.

For example, in the display region I, at least a portion of the first semiconductor chip 550 may overlap each of the light-emitting element layer 110 and the upper substrate 130 in the vertical direction DR3. For example, a lower surface 550b of the first semiconductor chip 550 may be coplanar with the lower surface 140b of the molding layer 140. However, the present disclosure is not limited thereto. In some example embodiments, the molding layer 140 may cover the lower surface 550b of the first semiconductor chip 550. Although not shown in FIG. 12, a heat transfer unit may be disposed on the lower surface 100b of the substrate 100 and in the display region I. In this case, the first semiconductor chip 550 may be spaced apart from the heat transfer unit in the first horizontal direction DR1.

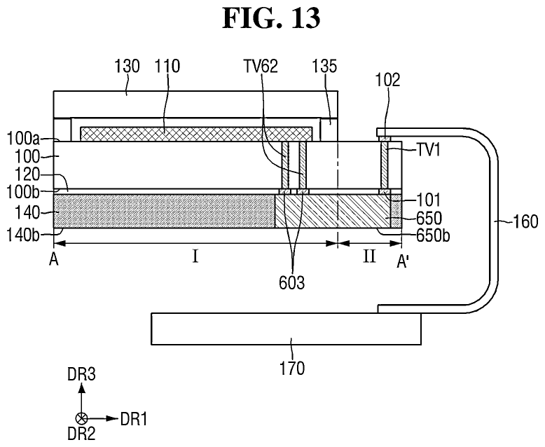

Hereinafter, with reference to FIG. 13, a display device according to still another example embodiment of the present disclosure will be described. Differences thereof from the display device as shown in FIG. 1 and FIG. 2 will be mainly described.

FIG. 13 is a cross-sectional view for illustrating a display device according to an example embodiment of the present disclosure.

Referring to FIG. 13, in the display device according to an example embodiment of the present disclosure, at least a portion of a first semiconductor chip 650 may overlap the light-emitting element layer 110 in the vertical direction DR3. Further, a second through-via TV62 may overlap each of the first semiconductor chip 650 and light-emitting element layer 110 in the vertical direction DR3.

For example, the first semiconductor chip 650 may be disposed on the lower surface 100b of the substrate 100 and in the display region I and the non-display region II. The first semiconductor chip 650 may be disposed in the molding layer 140. That is, the molding layer 140 may surround a sidewall of the first semiconductor chip 650.

For example, in the display region I, at least a portion of the first semiconductor chip 650 may overlap each of the light-emitting element layer 110 and the upper substrate 130 in the vertical direction DR3. For example, a lower surface 650b of the first semiconductor chip 650 may be coplanar with the lower surface 140b of the molding layer 140. However, the present disclosure is not limited thereto. In some example embodiments, the molding layer 140 may cover the lower surface 650b of the first semiconductor chip 650. Although not shown in FIG. 13, a heat transfer unit may be disposed on the lower surface 100b of the substrate 100 and in the display region I. In this case, the first semiconductor chip 650 may be spaced apart from the heat transfer unit in the first horizontal direction DR1.

The second through-via TV62 may extend through the substrate 100 in the vertical direction DR3 and may be disposed in the display region I. The second through-via TV62 may be disposed between an upper surface of the first semiconductor chip 650 and a lower surface of the light-emitting element layer 110. The first through-via TV1 may be spaced from the second through-via TV62 in the first horizontal direction DR1.

A third conductive pad 603 may be disposed on the lower surface 100b of the substrate 100 and in the display region I. The third conductive pad 603 may be disposed in the insulating layer 120. The third conductive pad 603 may be connected to each of the first semiconductor chip 650 and the second through-via TV62. For example, a lower surface of the second through-via TV62 may be connected to the third conductive pad 603. An upper surface of the second through-via TV62 may be connected to the light-emitting element layer 110. That is, the second through-via TV62 may electrically connect the first semiconductor chip 650 and the light-emitting element layer 110 to each other.

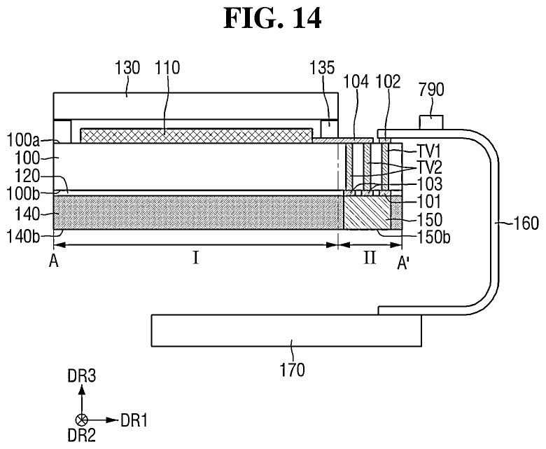

Hereinafter, with reference to FIG. 14, a display device according to still another example embodiment of the present disclosure will be described. Differences thereof from the display device as shown in FIG. 1 and FIG. 2 will be mainly described.

FIG. 14 is a cross-sectional view for illustrating a display device according to an example embodiment of the present disclosure.

Referring to FIG. 14, in a display device according to an example embodiment of the present disclosure, a second semiconductor chip 790 may be disposed on the thin-film substrate 160. For example, the second semiconductor chip 790 may be mounted on the thin-film substrate 160. For example, the second semiconductor chip 790 may include a connector or a memory semiconductor chip.

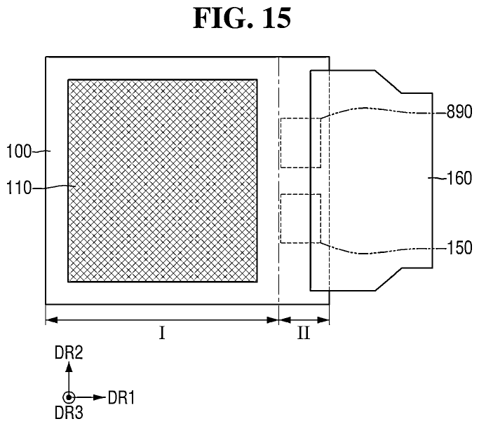

Hereinafter, a display device according to still another example embodiment of the present disclosure are described with reference to FIG. 2 and FIG. 15. Differences thereof from the display device as shown in FIG. 1 and FIG. 2 will be mainly described.

FIG. 15 is a cross-sectional view for illustrating a display device according to an example embodiment of the present disclosure.

Referring to FIG. 2 and FIG. 15, in the display device according to an example embodiment of the present disclosure, two semiconductor chips 150 and 890 may be disposed in the non-display region II.

For example, the third semiconductor chip 890 may be disposed on the lower surface 100b of the substrate 100 and in the non-display region II. The third semiconductor chip 890 may be spaced apart from the first semiconductor chip 150 in the second horizontal direction DR2. At least a portion of the third semiconductor chip 890 may overlap with the thin-film substrate 160 in the vertical direction DR3. For example, the third semiconductor chip 890 may include a display driver integrated circuit (DDI) or a timing controller (TCON).

FIG. 15 shows that the two semiconductor chips 150 and 890 are disposed in the non-display region I. However, this is intended only for convenience of description. The number of semiconductor chips disposed in the non-display region II is not limited thereto. That is, in some example embodiments, three or more semiconductor chips including a display driver integrated circuit (DDI) or a timing controller (TCON) may be disposed.

Although some example embodiments of the present disclosure have been described above with reference to the accompanying drawings, the present disclosure is not limited to the above example embodiments, but may be implemented in various different forms. A person skilled in the art will be able to appreciate that the present disclosure may be embodied in other concrete forms without changing the technical spirit or essential characteristics of the present disclosure. Therefore, it should be understood that the example embodiments as described above are not restrictive but illustrative in all respects.

What is claimed is:

1. A display device comprising:
a substrate including a display region and a non-display region adjacent to the display region in a first horizontal direction;
a light-emitting element layer on an upper surface of the substrate in the display region;
a thin-film substrate connected to the upper surface of the substrate in the non-display region;
a first semiconductor chip on a lower surface of the substrate, at least a portion of the first semiconductor chip overlapping with the thin-film substrate in a vertical direction; and
a first through-via in the non-display region, the first through-via extending through the substrate in the vertical direction, the first through-via electrically connecting the thin-film substrate and the first semiconductor chip to each other.

2. The display device of claim 1, wherein the substrate includes silicon (Si).

3. The display device of claim 1, further comprising:
a molding layer on the lower surface of the substrate, the molding layer surrounding a sidewall of the first semiconductor chip.

4. The display device of claim 3, wherein a sidewall of the substrate is aligned with a sidewall of the molding layer in the vertical direction.

5. The display device of claim 3, wherein a lower surface of the first semiconductor chip is coplanar with a lower surface of the molding layer.

6. The display device of claim 3, wherein the molding layer covers a lower surface of the first semiconductor chip.

7. The display device of claim 1, further comprising:
a second through-via in the non-display region, the second through-via extending through the substrate in the vertical direction, the second through-via spaced apart from the first through-via in the first horizontal direction, the second through-via electrically connected to the first semiconductor chip; and
a conductive pad on the upper surface of the substrate, the conductive pad electrically connecting the second through-via and the light-emitting element layer to each other.

8. The display device of claim 1, further comprising:
a heat transfer unit on the lower surface of the substrate, the heat transfer unit spaced apart from the first semiconductor chip in the first horizontal direction, the heat transfer unit configured to dissipate heat from an inside of the substrate.

9. The display device of claim 1, wherein at least a portion of the first semiconductor chip overlaps the light-emitting element layer in the vertical direction.

10. The display device of claim 9, further comprising:
a second through-via in the display region, the second through-via extending through the substrate in the vertical direction, the second through-via spaced apart from the first through-via in the first horizontal direction, the second through-via electrically connecting the first semiconductor chip and the light-emitting element layer to each other.

11. The display device of claim 1, further comprising:
a second semiconductor chip disposed on the thin-film substrate.

12. The display device of claim 1, further comprising:
a third semiconductor chip on the lower surface of the substrate, the third semiconductor chip spaced apart from the first semiconductor chip in a second horizontal direction different from the first horizontal direction, at least a portion of the third semiconductor chip overlapping the thin-film substrate in the vertical direction.

13. A display device comprising:
a substrate including silicon (Si);
a light-emitting element layer on an upper surface of the substrate;
a thin-film substrate connected to the upper surface of the substrate, the thin-film substrate spaced apart from the light-emitting element layer in a horizontal direction;
a first semiconductor chip on a lower surface of the substrate, at least a portion of the first semiconductor chip overlapping with the thin-film substrate in a vertical direction;
a molding layer on the lower surface of the substrate, the molding layer surrounding a sidewall of the first semiconductor chip; and
a first through-via extending through the substrate in the vertical direction, the first through-via electrically connecting the thin-film substrate and the first semiconductor chip to each other.

14. The display device of claim 13, further comprising:
a second through-via extending the substrate in the vertical direction, the second through-via spaced apart from the first through-via in the horizontal direction, the second through-via electrically connected to the first semiconductor chip; and
a conductive pad on the upper surface of the substrate, the conductive pad electrically connecting the second through-via and the light-emitting element layer to each other.

15. The display device of claim 13, further comprising:
a heat transfer unit on the lower surface of the substrate, the heat transfer unit spaced apart from the first semiconductor chip in the horizontal direction, the heat transfer unit overlapping the light-emitting element layer in the vertical direction, the heat transfer unit configured to dissipate heat from an inside of the substrate.

16. The display device of claim 15, wherein a lower surface of the first semiconductor chip, a lower surface of the molding layer, and a lower surface of the heat transfer unit are coplanar with each other.

17. The display device of claim 15, wherein the molding layer covers each of a lower surface of the first semiconductor chip and a lower surface of the heat transfer unit.

18. The display device of claim 13, wherein at least a portion of the first semiconductor chip overlaps the light-emitting element layer in the vertical direction.

19. The display device of claim 18, further comprising:
a second through-via extending through the substrate in the vertical direction, the second through-via spaced apart from the first through-via in the horizontal direction, the second through-via electrically connecting the first semiconductor chip and the light-emitting element layer to each other.

20. A display device comprising:
a substrate including a display region and a non-display region adjacent to the display region in a horizontal direction, the substrate including silicon (Si);
a light-emitting element layer on an upper surface of the substrate in the display region;
an upper substrate on the light-emitting element layer in the display region;
a thin-film substrate in the non-display region, one end of the thin-film substrate connected to the upper surface of the substrate;
a circuit board connected to an opposite end of the thin-film substrate;
a semiconductor chip on a lower surface of the substrate, at least a portion of the semiconductor chip overlapping with the thin-film substrate in a vertical direction;
a molding layer on the lower surface of the substrate, the molding layer surrounding a sidewall of the semiconductor chip, a lower surface of the molding layer being coplanar with a lower surface of the semiconductor chip, a sidewall of the molding layer aligned with a sidewall of the substrate in the vertical direction;
a first through-via in the non-display region, the first through-via extending through the substrate in the vertical direction, the first through-via electrically connecting the thin-film substrate and the semiconductor chip to each other;
a second through-via in the non-display region, to the second through-via extending through the substrate in the vertical direction, the second through-via spaced apart from the first through-via in the horizontal direction, the second through-via electrically connected to the semiconductor chip; and
a conductive pad on the upper surface of the substrate, the conductive pad electrically connecting the second through-via and the light-emitting element layer to each other.
